(19) United States
(12) Patent Application Publication
(10) Pub. No.: US 2015/0249064 A1
(43) Pub. Date: Sep. 3, 2015

(54) PREVENTION OF WARPING DURING HANDLING OF CHIP-ON-WAFER

(71) Applicant: International Business Machines Corporation, Armonk, NY (US)

(72) Inventors: Akihiro Horibe, Kanagawa-ken (JP); Yasumitsu Orii, Shiga-ken (JP)

(73) Assignee: International Business Machines Corporation, Armonk, NY (US)

(21) Appl. No.: 14/193,875

(22) Filed: Feb. 28, 2014

(51) Int. Cl. H01L 23/00; H01L 23/31; H01L 21/56; H01L 21/78; H01L 23/538

(52) U.S. Cl. CPC H01L 24/81; H01L 21/78; H01L 24/17; H01L 23/5384; H01L 21/563; H01L 23/3157; H01L 2224/81801

(57) ABSTRACT

To reduce the risk of reduction in yield due to breakage of a thin wafer or a thin chip having through silicon vias (TSVs) formed therein in a chip bonding process, and to prevent warping during handling of a chip-on-wafer (CoW). Chips are bonded to a wafer having TSVs formed therein and sealed before the wafer is thinned. Subsequently, the CoW is subjected to a process of thinning the TSV wafer, a back-surface treatment, and a process of cutting the wafer into small pieces by dicing. Although thin wafers and thin chips having TSVs formed therein are difficult to handle since the chips are bonded to the wafer before thinning and the wafer is thinned and cut into small pieces while mechanical strength thereof is increased by fixing a support to the wafer, the yield of three-dimensional stacked devices can be increased.

### BACKGROUND OF THE INVENTION

1. Field of the Invention

The present invention relates to a semiconductor mounting method, and more particularly, to a technology for preventing warping during handling of a chip-on-wafer (CoW).

2. Description of Related Art

A method for producing a three-dimensional mounting device requires a high yield, low cost process. It is desirable to employ an organic substrate and perform solder bonding in a reflow oven to achieve high performance and low cost. A through silicon via (TSV) wafer is a wafer in which TSVs are formed. A TSV chip is a chip in which TSVs are formed.

FIG. 1 illustrates a silicon wafer in which TSVs do not extend to one of top and bottom surfaces of the silicon wafer and are in a partially penetrating, or incomplete state and a silicon wafer in which TSVs extend to both top and bottom surfaces of the silicon wafer and are in a completely penetrating, or complete, state. Silicon wafers are known to be typically disc-shaped, and have a thickness of about 800 μm before thinning and about 50 to 100 μm, which is extremely small, after through vias are formed. Therefore, the wafers easily warp when the wafers are handled before being cut into small pieces by dicing, and there is a risk that warping or breakage will occur unless the wafers are handled very carefully.

The TSVs function as electrical communication paths between a top surface (or front surface) and a bottom surface (or back surface), and are in a completely penetrating (complete) state when the TSVs extend to both the top and bottom surfaces. A rewiring layer may be formed near an outermost surface. The material of the wafers is not limited to silicon, and the material of the vias is not limited to Cu.

It is difficult to form TSVs having a large aspect ratio in a process of forming the TSVs in a TSV wafer or a TSV chip. The aspect ratio of a TSV is a ratio expressed as β (depth)/α (diameter). It is desirable to reduce a from the viewpoint of increasing the wiring density. On the other hand, it is technically difficult to cut via holes and fill them so as to increase β. This is the reason why it is difficult to increase the aspect ratio of the TSVs. If TSVs having a large diameter are formed, there is a risk that device performance will be degraded owing to an internal stress caused by a difference in coefficient of linear expansion between the material of the TSVs and the material of the wafer, that is, silicon. As a result, the diameter of the TSVs tends to be reduced, and necessarily the thickness of the TSV chips also tends to be reduced.

The thin TSV chips warp by a not inconsiderable amount due to asymmetry between structures at front and back sides, such as a silicon device layer, a wiring layer, and electrodes on outer layers. The warping of the TSV chips causes a problem of, in particular, a bonding failure in a chip bonding process performed in a reflow oven. FIG. 2 illustrates the problem that warping of a TSV chip causes a bonding failure in a chip bonding process performed in a reflow oven in manufacturing of a three-dimensional stacked device. According to the procedure illustrated in FIG. 2(a), a separate thin single TSV chip cannot tolerate the thermal expansion that occurs in a reflow process for bonding the TSV chip to an organic substrate.

In addition, because the thin TSV chip warps by a large amount owing to a difference in coefficient of thermal expansion (CTE) between the TSV chip and the organic substrate, it is difficult to mount a top chip onto the TSV chip by a reflow process. With the procedure illustrated in FIG. 2(b), it is necessary to apply solder to the bottom of the TSV chip after bonding the TSV chip to the top chip. Therefore, the process of applying solder to the bottom of the TSV chip needs to be performed for each chip. This makes the procedure impractical from the viewpoint of process cost. Neither of the procedures illustrated in FIGS. 2(a) and 2(b) can easily solve the problem that a bonding failure, including a bonding displacement or breakage of a chip, occurs in a reflow bonding process for bonding the chip, and it is difficult to solve this problem.

Technologies in the prior art are directed to preventing warping and flattening technologies using an adhesive layer. However, in particular, past technologies do not provide for the “preparation of a silicon wafer in which TSVs do not extend to a bottom surface of the silicon wafer, and scraping of the bottom surface so that the TSVs extend to the bottom surface while a support is fixed to the silicon wafer.”

### SUMMARY OF THE INVENTION

One aspect of the present invention provides a method for preventing warping of a TSV wafer before thinning in a process of handling the TSV wafer before thinning. The method includes the steps of: arranging a plurality of chips so that the chips correspond to TSVs; fixing the plurality of chips to the TSV wafer before thinning with a plurality of solder bumps to produce fixed chips; sealing a space between each chip and the TSV wafer before thinning with an underfill material to produce sealed chips; fixing a support so that the support covers the fixed and sealed chips; scraping a surface to which the TSVs do not extend while the support is fixed until the TSVs appear and are in a completely penetrating state; and dicing the TSV wafer before thinning along a region where the chips are not arranged.

Another aspect of the present invention provides a method for preventing warping of a TSV wafer after thinning in a process of handing the TSV wafer after thinning. The method includes the steps of: arranging a plurality of chips fixed to a top surface so that the chips correspond to TSVs; melting a plurality of solder bumps to fix the plurality of chips and produce fixed chips; sealing a space between each chip and the TSV wafer after thinning with an underfill material to produce sealed chips; fixing a support so that the support covers the fixed and sealed chips; arranging solder bumps on the bottom surface of the TSV wafer after thinning so that the solder bumps correspond to the TSVs; melting the solder bumps to fix the solder bumps to the bottom surface of the TSV wafer after thinning by and produce fixed solder bumps; and dicing the TSV wafer after thinning along a region where the chips and the fixed solder bumps fixed are not arranged.

Another aspect of the present invention provides a chip-on-wafer having TSVs where the TSVs do not extend to one of top and bottom surfaces of a wafer and are in a partially penetrating state, where a plurality of chips are arranged so as to correspond to the TSVs and are fixed by melting a plurality of solder bumps, and where a space between each chip and the wafer is sealed with an underfill material.

### BRIEF DESCRIPTION OF THE DRAWINGS

FIG. 1 illustrates a silicon wafer in which TSVs. do not extend to one of top and bottom surfaces of the silicon wafer and are in a partially penetrating state and a silicon wafer in which TSVs extend to both top and bottom surfaces of the silicon wafer and are in a completely penetrating state.

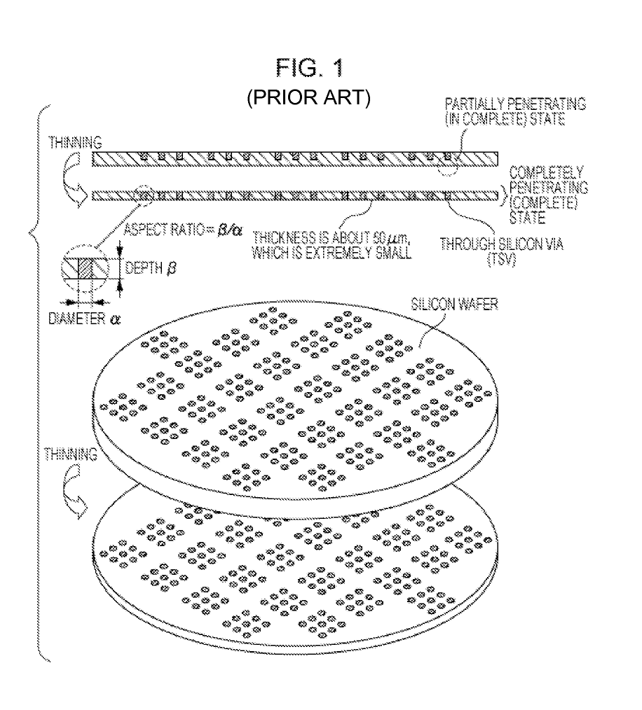

FIG. 2 illustrates a problem that warping of a TSV chip causes a bonding failure in a chip bonding process performed in a reflow oven in manufacturing of a three-dimensional stacked device.

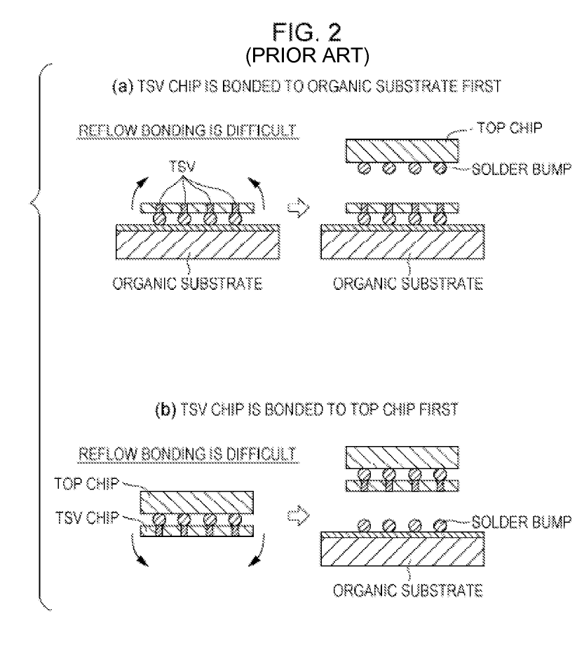

FIG. 3 illustrates a process according to a first embodiment of the present invention.

FIG. 4 illustrates an application process according to the first embodiment of the present invention.

FIG. 5 illustrates a process according to a second embodiment of the present invention.

FIG. 6 illustrates an application process according to the second embodiment of the present invention.

FIG. 7 illustrates a process according to a third embodiment of the present invention.

FIG. 8 illustrates an application process according to the third embodiment of the present invention.

FIG. 9 illustrates a process of cutting a wafer into small pieces to change the wafer from a state in which a plurality of chips are mounted thereon to a state in which a single chip is mounted on each of the small pieces according to the present invention.

### DETAILED DESCRIPTION OF THE PREFERRED EMBODIMENTS

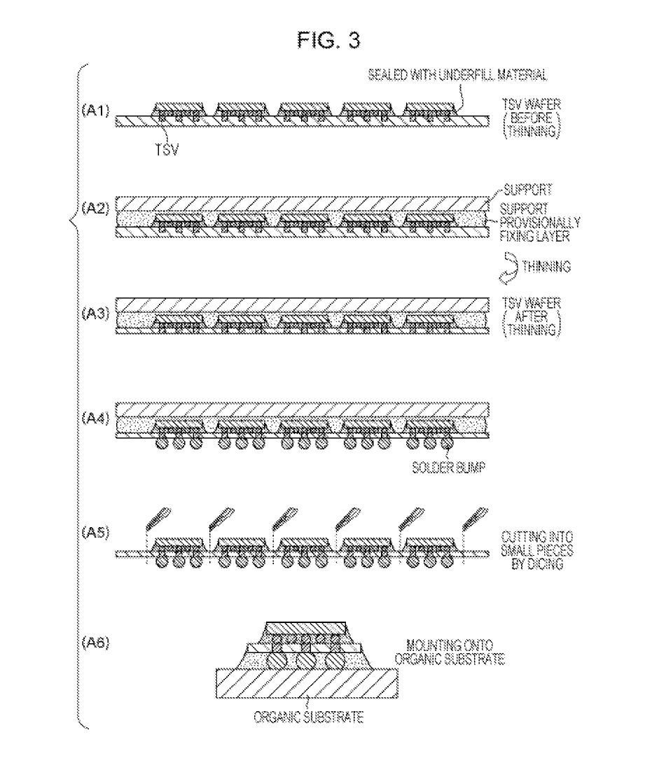

FIG. 3 illustrates a process according to a first embodiment of the present invention. In step A1, a silicon wafer in which TSVs do not extend to one of top and bottom surfaces of the silicon wafer and are in a partially penetrating, or incomplete, state is prepared. The wafer in this state can be referred to as a “TSV wafer (before thinning)” or a “wafer before thinning”.

A plurality of chips, which have already been tested and completed, are arranged so as to correspond to the TSVs, and are fixed by melting a plurality of solder bumps. It is assumed that the chips are simultaneously bonded in a reflow oven after being provisionally fixed with a flux. However, the method for bonding the chips is not limited to this, and the chips may also be stacked in multiple stages. The chips can be those that have already been tested and completed. A space between each chip and the silicon wafer is sealed with an underfill material. Since the space is sealed, sufficient resistance to an external mechanical force is provided.

Although it is assumed that simultaneous bonding is performed in a reflow oven, the bonding process is not limited to this, and bonding using a pre-applied underfill material or cold bonding can instead be performed. The wafer on which chips are mounted as described above can be referred to as a “chip-on-wafer (CoW)”. In step A2, a support is fixed so as to cover the fixed and sealed chips. The support increases the rigidity. Chips having a height, or thickness, of about 100 to 800 μm have been put into practical use. A support that provisionally fixes the layer can be used to fix the support. Typically, an adhesive may be used.

The wafer that is an intermediate product in step A2 has a new structural feature in that the TSVs are in a partially penetrating, or incomplete, state. A thinning process is performed between steps A2 and A3. Specifically, the surface of the wafer to which the TSVs do not extend is scraped, i.e., the wafer is thinned, while the support is fixed until the TSVs appear and are in a completely penetrating, complete, state. The surface can be scraped by applying a mechanical stress.

Alternatively, a chemical method can be used instead of the mechanical scraping method. An insulating film, a rewiring film, an electrode, or the like can be formed as necessary on the wafer surface that has been subjected to thinning. A method for forming the electrode is not particularly limited. For example, a plating method or a ball mounting method can be used. In step A4, solder bumps can be arranged on the TSVs that have appeared and are in a completely penetrating state. A method for forming the bumps is not particularly limited. For example, a plating method, or C4NP can be used.

In step A5, the silicon wafer is diced along regions where the chips are not arranged. The support can be fixed to the wafer until the dicing process is finished. The dicing process can be performed by applying a mechanical stress. The dicing process can be performed by cutting the silicon wafer into small pieces to change the wafer from a state in which a plurality of chips are mounted thereon to a state in which a single chip is mounted on each of the small pieces. In step A6, an organic substrate is prepared, and a plurality of solder bumps are prepared on the organic substrate. One of the small pieces into which the silicon wafer has been cut is placed on the prepared solder bumps, and is fixed by melting the solder bumps.

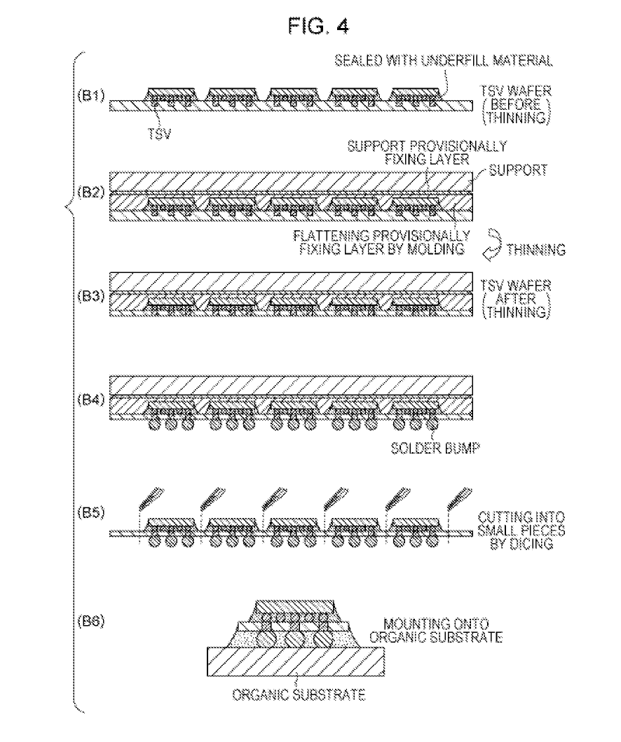

In the case where solder bumps are arranged on the TSVs that have appeared and are in a completely penetrating state in step A4, an organic substrate is prepared, and one of the small pieces into which the silicon wafer has been cut is placed on the organic substrate and is fixed by melting the solder bumps. FIG. 4 illustrates an application process according to the first embodiment of the present invention. For purposes of the description herein, only differences between steps A1 to A6 and steps B1 to B6 are described. In step B2, a flattening provisionally fixing layer is formed by molding, and then a support provisionally fixing layer for fixing the support is formed.

Since molding is performed, a flat surface for fixing the support can be more easily formed. In addition, a high rigidity material can be used to form the flattening provisionally fixing layer, and a material expected to be highly adhesive to the support, i.e., material that can be easily bonded to an attachment surface of the support, can be used to form the support provisionally fixing layer. The support provisionally fixing layer, which is an adhesive layer, can serve to smooth irregularities on the flattening provisionally fixing layer. The characteristics of the flattening provisionally fixing layer and the support provisionally fixing layer can be selected so that the support can be easily removed when the reinforcement by the support is no longer necessary.

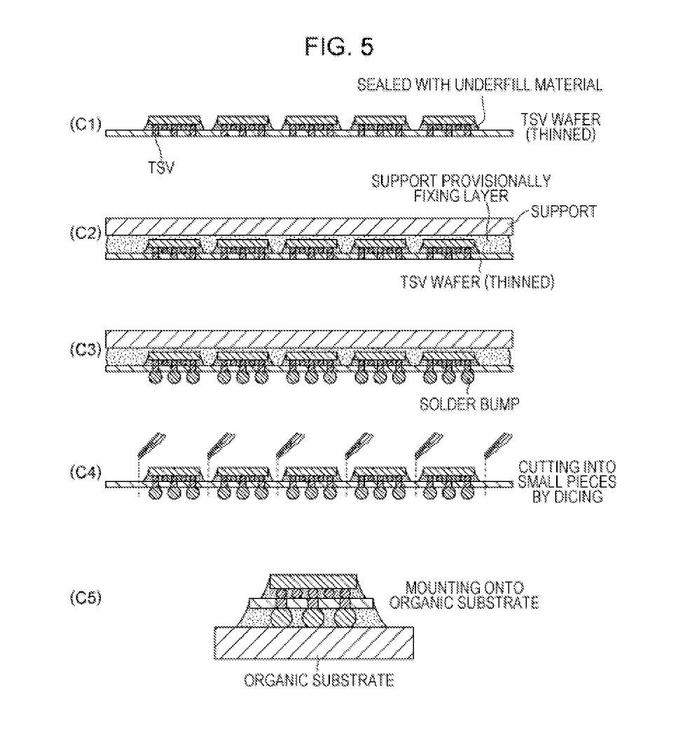

A resin curable by light, heat, or the like, can be used in the molding process. The support provisionally fixing layer can be formed by, for example, a spin-coating technology. FIG. 5 illustrates a process according to a second embodiment of the present invention. In step C1, a silicon wafer in which TSVs extend to both top and bottom surfaces of the silicon wafer and are in a completely penetrating state is prepared. The wafer in this state can be referred to as a “thinned wafer” or a “wafer after thinning.” A plurality of chips, which have already been tested and completed, are arranged on the top surface of the silicon wafer so as to correspond to the TSVs, and are fixed by melting a plurality of solder bumps. The chips can be those that have already been tested and completed. A space between each chip and the silicon wafer is sealed with an underfill material. In step C2, a support is fixed so as to cover the fixed and sealed chips. The support increases the rigidity. In step C3, solder bumps are arranged on the bottom surface of the silicon wafer so as to correspond to the TSVs.

The solder bumps are fixed to the bottom surface of the silicon wafer by melting the solder bumps. The wafer that is an intermediate product in step C3 has a new structural feature in that the support is fixed so as to cover the chips and the solder bumps are fixed to the bottom surface of the silicon wafer. In step C4, the silicon wafer is diced along regions where the chips and the solder bumps fixed by being melted are not arranged. The support can be maintained in the fixed state until the dicing process is finished, so that sufficient resistance to the mechanical stress can be ensured during the dicing process.

The dicing process can be performed by cutting the silicon wafer into small pieces to change the wafer from a state in which a plurality of chips are mounted thereon to a state in which a single chip is mounted on each of the small pieces. In step C5, an organic substrate is prepared, and a plurality of solder bumps are prepared on the organic substrate. One of the small pieces into which the silicon wafer has been cut is placed on the prepared solder bumps, and is fixed by melting the solder bumps. In the case where solder bumps are arranged on the TSVs that have appeared and are in a completely penetrating state in step C5, an organic substrate is prepared, and one of the small pieces into which the silicon wafer has been cut is placed on the organic substrate, and is fixed by melting the solder bumps.

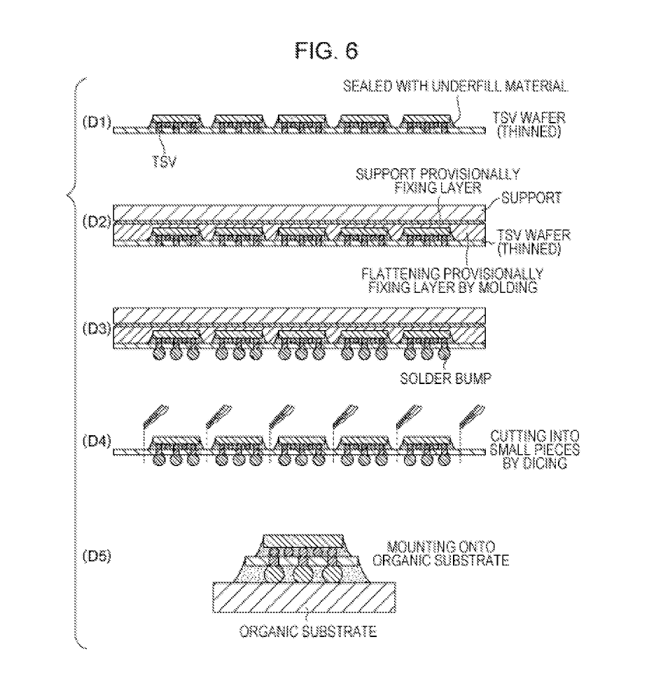

FIG. 6 illustrates an application process according to the second embodiment of the present invention. This application process is similar to the application process according to the first embodiment except that the TSV wafer is a wafer after thinning or a thinned wafer in step D2.

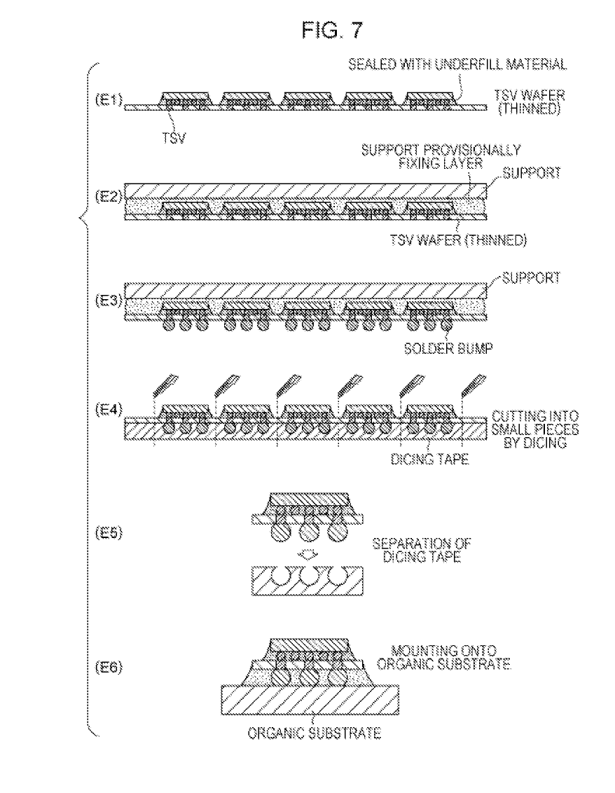

FIG. 7 illustrates a process according to a third embodiment of the present invention. In step E4, a piece of dicing tape is prepared before the wafer is diced, and the solder bumps fixed to the bottom surface of the wafer are placed on the piece of dicing tape. The piece of dicing tape itself can have a reinforcing function. Variations in height caused by variations in diameter of the solder bumps can be absorbed by the piece of dicing tape.

Although the support is removed in step E4, dicing is preferably performed while the piece of dicing tape is attached in the state where the support is not yet removed—in other words, while the original function of the dicing tape is achieved. In step E5, the piece of dicing tape is removed. It can be effective to apply a release agent or the like in advance. Instead of removing the piece of dicing tape, the main body can be removed from the piece of dicing tape.

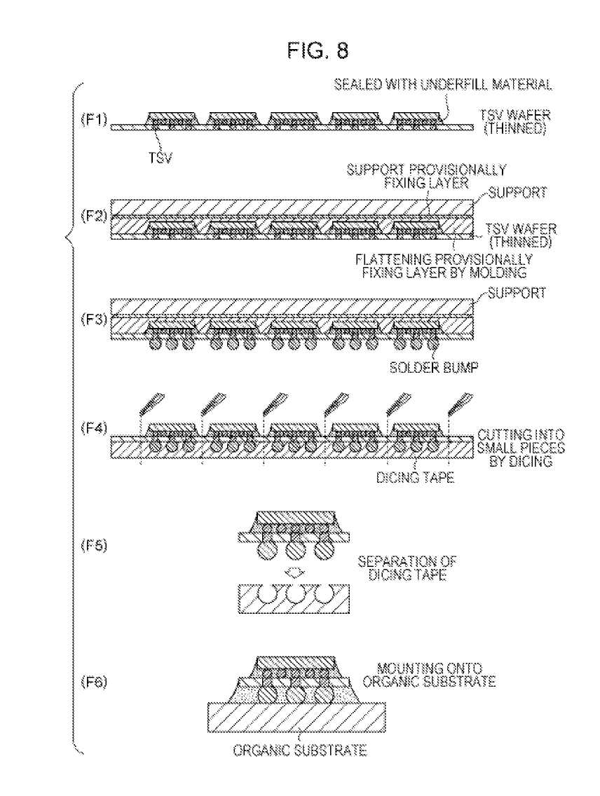

FIG. 8 illustrates an application process according to the third embodiment of the present invention. This application process is similar to the application process illustrated in FIG. 4 based on the process of FIG. 3 and the application process illustrated in FIG. 6 based on the process of FIG. 5, therefore explanations thereof are omitted. The third embodiment of the present invention can be applied to both the first and second embodiments of the present invention.

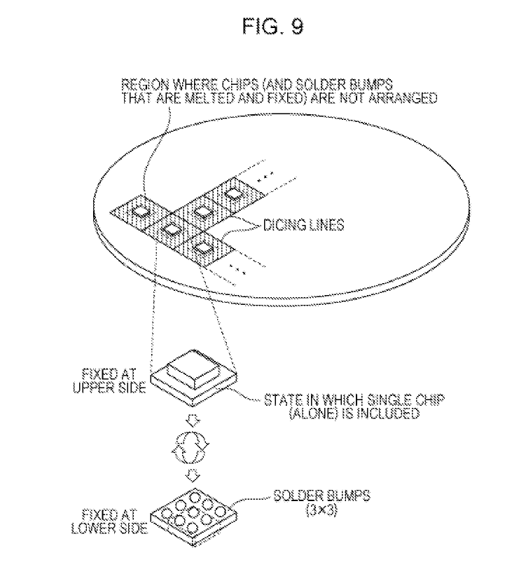

FIG. 9 illustrates a process of cutting a wafer into small pieces to change the wafer from a state in which a plurality of chips are mounted thereon to a state in which a single chip is mounted on each of the small pieces according to the present invention. With regard to the term “single chip”, a state in which “a plurality of chips” are mounted on each of the small pieces is also included. Each of the small pieces into which the wafer has been cut has components mounted and fixed to both surfaces thereof, thereby serving as a three-dimensional mounting device with an increased rigidity.

The main characteristic of the present invention is the order in which processes of a method are performed. The present invention can also be realized as a system in which a robot or the like automatically executes each step of the method.

We claim:

1. A method for preventing warping of a through silicon via (TSV) wafer before thinning in a process of handling the TSV wafer before thinning, the method comprising the steps of:
arranging a plurality of chips so that the chips correspond to TSVs;
fixing the plurality of chips to the TSV wafer before thinning with a plurality of solder bumps to produce fixed chips;
sealing a space between each chip and the TSV wafer with an underfill material to produce sealed chips;
fixing a support so that the support covers the fixed and sealed chips;
scraping a surface to which the TSVs do not extend while the support is fixed until the TSVs appear and are in a completely penetrating state; and
dicing the TSV wafer before thinning along a region where the chips are not arranged.

2. A method for preventing warping of a through silicon via (TSV) wafer after thinning in a process of handling the TSV wafer after thinning, the method comprising the steps of:
arranging a plurality of chips fixed to a top surface so that the chips correspond to TSVs;
melting a plurality of solder bumps to fix the plurality of chips and produce fixed chips;
sealing a space between each chip and the TSV wafer after thinning with an underfill material to produce sealed chips;
fixing a support so that the support covers the fixed and sealed chips;
arranging solder bumps on the bottom surface of the TSV wafer after thinning so that the solder bumps correspond to the TSVs; melting the solder bumps to fix the solder bumps to the bottom surface of the TSV wafer after thinning by and produce fixed solder bumps; and
dicing the TSV wafer after thinning along a region where the chips and the fixed solder bumps fixed are not arranged.

3. The method according to claim 1, further comprising:
preparing a piece of dicing tape; and
placing the solder bumps fixed to the bottom surface of the silicon wafer on the piece of dicing tape,
wherein the steps of preparing the piece of dicing tape and placing the solder bumps fixed to the bottom surface of the silicon wafer on the piece of dicing tape are performed before the step of dicing the silicon wafer.

4. The method according to claim 2, further comprising:
preparing a piece of dicing tape; and
placing the solder bumps fixed to the bottom surface of the silicon wafer on the piece of dicing tape,
wherein the steps of preparing the piece of dicing tape and placing the solder bumps fixed to the bottom surface of the silicon wafer on the piece of dicing tape are performed before the step of dicing the silicon wafer.

5. The method according to claim 1, wherein the step of dicing the silicon wafer along the region where the chips are not arranged is performed by cutting the silicon wafer into small pieces to change the silicon wafer from a state in which the chips are mounted thereon to a state in which a single chip or a plurality of chips are mounted on each of the small pieces.

6. The method according to claim 2, wherein the step of dicing the silicon wafer along the region where the chips and the solder bumps fixed by being melted are not arranged is performed by cutting the silicon wafer into small pieces to change the silicon wafer from a state in which the chips are mounted thereon to a state in which a single chip or a plurality of chips are mounted on each of the small pieces.

7. The method according to claim 1, further comprising:
preparing an organic substrate;
preparing a plurality of solder bumps on the organic substrate; and
placing one of small pieces into which the silicon wafer has been cut on the prepared solder bumps and fixing the one of the small pieces into which the silicon wafer has been cut by melting the solder bumps.

8. The method according to claim 2, further comprising:
preparing an organic substrate; and
placing one of small pieces into which the silicon wafer has been cut on the organic substrate and fixing the one of the small pieces into which the silicon wafer has been cut by melting the solder bumps.

9. A chip-on-wafer comprising: through silicon vias (TSVs) wherein the TSVs do not extend to one of top and bottom surfaces of a wafer and are in a partially penetrating state, wherein a plurality of chips are arranged so as to correspond to the TSVs and are fixed by melting a plurality of solder bumps, and wherein a space between each chip and the wafer is sealed with an underfill material.
